(19) United States
(12) Patent Application Publication
(10) Pub. No.: US 2015/0000871 A1
(43) Pub. Date: Jan. 1, 2015

(54) HOUSING WITH HEAT PIPES INTEGRATED INTO ENCLOSURE FINS

(71) Applicant: Hamilton Sundstrand Corporation, Charlotte, NC (US)

(72) Inventors: Rachel Farner, Springfield, MA (US); Jay W. Kokas, East Granby, CT (US); Kenneth J. Trotman, Granby, CT (US); Kerry R. Querns, Durham, CT (US)

(21) Appl. No.: 13/932,651

(22) Filed: Jul. 1, 2013

(51) Int. Cl. H05K 7/20

(52) U.S. Cl. CPC H05K 7/20336
USPC 165/104.21

(57) ABSTRACT

A device with increased heat dissipation abilities for supporting printed wiring boards includes a chassis for holding printed wiring boards, a plurality of fins attached to the chassis, and a heat pipe in each of the plurality of fins that is capable of transferring heat from the chassis to the surrounding ambient by absorbing heat from the chassis at a first end of the heat pipe and releasing the heat into the ambient at a second end of the heat pipe.

### BACKGROUND

The present invention relates to cooling apparatuses for printed wiring boards, and in particular, to a housing for printed wiring boards with improved heat dissipation abilities.

Thermal management of aircraft mounted electronic components is becoming increasingly more challenging with the higher density of more powerful, but smaller electronic components. Electronic components are held on printed wiring boards that mechanically support and electrically connect the electronic components. Printed wiring boards absorb heat generated by the electronic components. High heat can damage printed wiring boards and limit the life of the printed wiring board. High heat can also damage the electronic components and cause them to become unreliable. For these reasons, cooling systems and device are needed to remove heat from printed wiring boards.

Due to space limitations on aircrafts, printed wiring boards are typically stacked in a printed wiring board stack-up. A printed wiring board stack-up is typically held in a housing or chassis that supports the printed wiring board stack-up. The housing or chassis also acts as a cooling apparatus for the printed wiring boards. Heat can transfer through the printed wiring boards to the housing or chassis and can then be dispelled into an ambient. Housings and chassis can have fins running on an outside surface to provide more contact area with the ambient to increase the heat dissipation abilities of the housing or chassis.

### SUMMARY

A device with increased heat dissipation abilities for supporting printed wiring boards includes a chassis for holding printed wiring boards, a plurality of fins attached to the chassis, and a heat pipe in each of the plurality of fins that is capable of transferring heat from the chassis to the surrounding ambient by absorbing heat from the chassis at a first end of the heat pipe and releasing the heat into the ambient at a second end of the heat pipe.

A device with increased heat dissipation abilities for supporting printed wiring boards includes a housing that supports a plurality of printed wiring boards on ledges that run along interior surfaces of the housing, a plurality of fins connected to a first side and a second side of the housing, a cavity in each of the plurality of fins, and a heat pipe in the cavity in each of the plurality of fins to transfer heat generated by the printed wiring boards in the housing to an ambient surrounding the housing.

A method for cooling printed wiring boards includes transferring heat generated on a printed wiring board to a chassis in which the printed wiring board is held, absorbing heat into a heat pipe that is positioned in a hollow fin on the chassis, transferring the heat through the heat pipe, and releasing the heat from the heat pipe into an ambient.

### BRIEF DESCRIPTION OF THE DRAWINGS

FIG. 1 is a perspective view of a chassis that is capable of holding printed wiring boards.

FIG. 2 is a cross-sectional view of the chassis showing heat pipes running through fins on the chassis, taken along line 2-2 of FIG. 1.

FIG. 3 is a cross-sectional view of the chassis with printed wiring boards, taken along line 2-2 of FIG. 1.

### DETAILED DESCRIPTION

In general, the present invention relates to cooling devices for printed wiring boards. Printed wiring boards can be stacked on top of each other in locations where space is limited. Printed wiring board stack-ups are typically supported by a chassis with fins. The chassis acts as a cooling apparatus for the printed wiring board stack-up, as heat can transfer from the printed wiring boards through the chassis and fins into an ambient. Placing heat pipes in the fins can increase the amount of heat that can be transferred through the fins of the chassis, as heat pipes enable more efficient and effective use of the fin area.

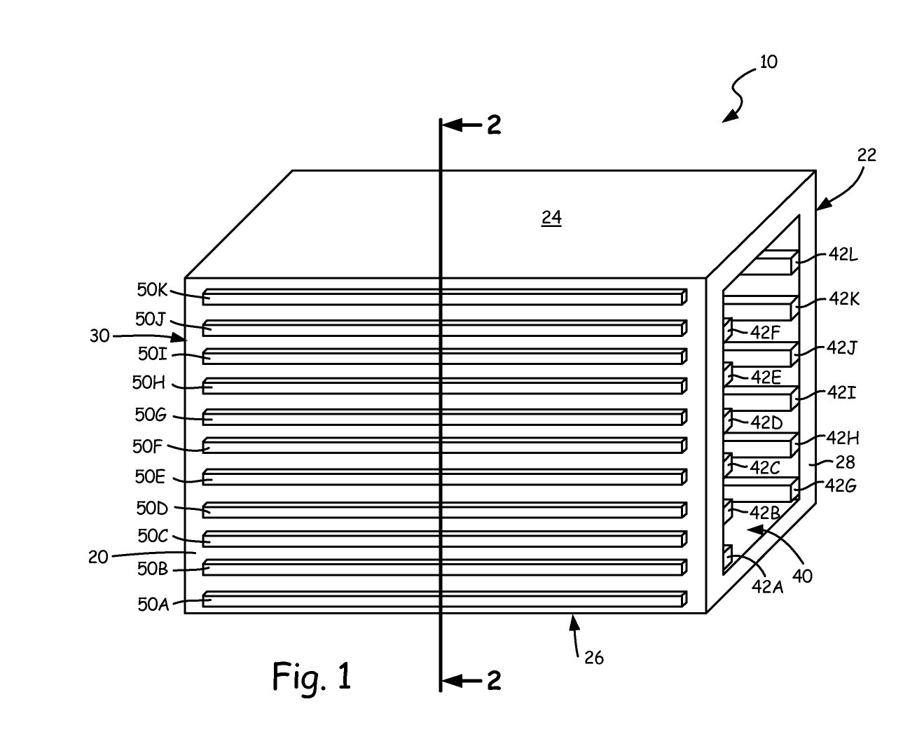

FIG. 1 is a perspective view of chassis 10 that is capable of holding printed wiring boards. Chassis 10 includes first side 20, second side 22, top side 24, bottom side 26, first end 28, second end 30, cavity 40, ledges 42 (including ledge 42A, ledge 42B, ledge 42C, ledge 42D, ledge 42E, ledge 42F, ledge 42G, ledge 42H, ledge 42I, ledge 42J, ledge 42K, and ledge 42L), and fins 50 (including fin 50A, fin 50B, fin 50C, fin 50D, fin 50E, fin 50F, fin 50G, fin 50H, fin 50I, fin 50J, and fin 50K).

Chassis 10 is a housing that is capable of holding printed wiring boards. Chassis 10 has first side 20 that is opposite second side 22, top side 24 that is opposite bottom side 26, and first end 28 that is opposite second end 30. In the embodiment shown, chassis 10 is made out of aluminum. In alternate embodiments, chassis 10 can be made out of any suitable material that is capable of supporting and cooling printed wiring boards. Chassis 10 can be manufactured with any suitable manufacturing process, including machining or casting. Chassis 10 can hold printed wiring boards in cavity 40. In the embodiment shown in FIG. 1, cavity 40 runs through chassis 10 with a first opening at first end 28 and a second opening at second end 30. In alternate embodiments, cavity 40 can run through chassis 10 in any direction and chassis 10 can have any number of openings.

Positioned in cavity 40 are ledges 42. Ledges 42 are rectangular shaped flanges that extend longitudinally from first end 28 to second end 30 along a first interior side of cavity 40 (shown in FIG. 1 as ledges 42A-42F) and a second interior side of cavity 40 (shown in FIG. 1 as ledges 42G-42L). Ledges 42 are positioned in cavity 40 to provide a support upon which printed wiring boards can be supported. Ledges 42 can be manufactured with chassis 10 or added to chassis 10 after it has been manufactured.

Fins 50 are positioned on first side 20 and second side 22 of chassis 10. In the embodiment shown in FIG. 1, fins 50 are rectangular shaped flanges that extend longitudinally from first end 28 to second end 30 along an exterior surface of first side 20 and second side 22. In alternate embodiments, fins 50 can have any suitable shape and can be placed on any number of sides of chassis 10. Fins 50 can be manufactured with chassis 10 or added to chassis 10 after it has been manufactured. Fins 50 are positioned on chassis 10 to dispel heat from chassis 10 into an ambient. Chassis 10 can be positioned in an aircraft so that cooling air flows around and between fins 50.

Chassis 10 is cooled with convective heat transfer. Convective heat transfer transfers heat through the movement of fluids, and more specifically from a hotter location to a cooler location by moving a cooler fluid over a warmer location. Chassis 10 is cooled when cooling air flows around chassis 10, as the cooling air moves over the solid surface of chassis 10 to absorb heat from chassis 10.

Placing fins 50 on chassis 10 is advantageous, as fins 50 increase the amount of surface area that cooling air can touch when cooling air is flowing around chassis 10. The location and quantity of fins 50 on chassis 10 can vary to maximize cooling efficiency for any given application. The efficiency of convective heat transfer improves as the surface area between the hotter location and the cooler fluid increases, as there are more areas where heat can transfer out of chassis 10 into the cooling fluid. Having more effective convective heat transfer is advantageous, as it will improve the overall cooling of chassis 10.

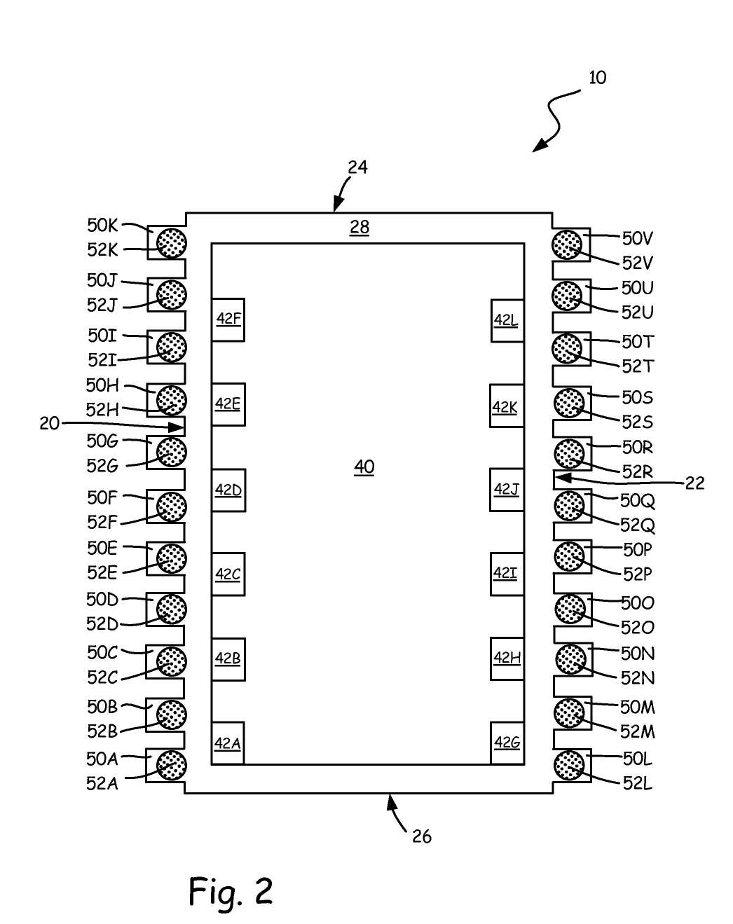

FIG. 2 is a cross-sectional view of chassis 10 showing heat pipes 52 running through fins 50 on chassis 10, taken along line 2-2 of FIG. 1. Chassis 10 includes first side 20, second side 22, top side 24, bottom side 26, cavity 40, ledges 42 (including ledge 42A, ledge 42B, ledge 42C, ledge 42D, ledge 42E, ledge 42F, ledge 42G, ledge 42H, ledge 42I, ledge 42J, ledge 42K, and ledge 42L), fins 50 (including fin 50A, fin 50B, fin 50C, fin 50D, fin 50E, fin 50F, fin 50G, fin 50H, fin 50I, fin 50J, fin 50K, fin 50L, fin 50M, fin 50N, fin 50O, fin 50P, fin 50Q, fin 50R, fin 50S, fin 50T, fin 50U, and fin 50V), and heat pipes 52 (including heat pipe 52A, heat pipe 52B, heat pipe 52C, heat pipe 52D, heat pipe 52E, heat pipe 52F, heat pipe 52G, heat pipe 52H, heat pipe 52I, heat pipe 52J, heat pipe 52K, heat pipe 52L, heat pipe 52M, heat pipe 52N, heat pipe 52O, heat pipe 52P, heat pipe 52Q, heat pipe 52R, heat pipe 52S, heat pipe 52T, heat pipe 52U, and heat pipe 52V).

Chassis 10 is capable of holding printed wiring boards in cavity 40. Cavity 40 runs longitudinally through chassis 10 from a first end to a second end. In the embodiment shown in FIG. 2, cavity 40 includes six ledges 42 on a first interior surface and six ledges 42 on a second interior surface. In alternate embodiments, the number of ledges in chassis 10 can vary. Ledges 42 are positioned in cavity 40 to support printed wiring boards. Ledges 40 are rectangular shaped flanges that extend inwards from chassis 10.

Cavity 40 has ledges 42A-42F positioned on a first interior side and ledges 42G-42L positioned on a second interior side. Ledge 42A runs longitudinally through cavity 40 above bottom side 26 and below ledge 42B; ledge 42B runs longitudinally through cavity 40 between ledge 42A and ledge 42C; ledge 42C runs longitudinally through cavity 40 between ledge 42B and ledge 42D; ledge 42D runs longitudinally through cavity 40 between ledge 42C and ledge 42E; ledge 42E runs longitudinally through cavity 40 between ledge 42E and ledge 42F; and ledge 42F runs longitudinally through cavity 40 above ledge 42E and below top side 24; ledge 42G runs longitudinally through cavity 40 above bottom side 26 and below ledge 42H; ledge 42H runs longitudinally through cavity 40 between ledge 42G and ledge 42I; ledge 42I runs longitudinally through cavity 40 between ledge 42H and ledge 42J; ledge 42J runs longitudinally through cavity 40 between ledge 42I and ledge 42K; ledge 42K runs longitudinally through cavity 40 between ledge 42J and ledge 42L; and ledge 42L runs longitudinally through cavity 40 above ledge 42K and below top side 24.

Fins 50 are positioned on first side 20 and second side 22 of chassis 10 in the embodiment shown in FIG. 2. In alternate embodiments, the number of fins on each side can vary and fins 50 can be positioned on any number of sides of chassis 10 with any arrangement. Fins 50A-50K run longitudinally across first side 20 from a first end to a second end of chassis 10 and fins 50L-50V run longitudinally across second side 22 from a first end to a second end of chassis 10. Fin 50A is positioned above bottom side 26 and below fin 50B; fin 50B is positioned between fin 50A and fin 50C; fin 50C is positioned between fin 50B and fin 50D; fin 50D is positioned between fin 50C and fin 50E; fin 50E is positioned between fin 50D and fin 50F; fin 50F is positioned between fin 50E and fin 50G; fin 50G is positioned between fin 50F and fin 50H; fin 50H is positioned between fin 50G and fin 50I; fin 50I is positioned between fin 50H and fin 50J; fin 50J is positioned between fin 50I and fin 50K; fin 50K is positioned above fin 50A and below top side 24; fin 50L is positioned above bottom side 26 and below fin 50M; fin 50M is positioned between fin 50L and fin 50N; fin 50N is positioned between fin 50M and fin 50O; fin 50O is positioned between fin 50N and fin 50P; fin 50P is positioned between fin 50O and fin 50Q; fin 50Q is positioned between fin 50P and fin 50R; fin 50R is positioned between fin 50Q and fin 50S; fin 50S is positioned between fin 50R and fin 50T; fin 50T is positioned between fin 50S and fin 50U; fin 50U is positioned between fin 50T and fin 50V; fin 50V is positioned above fin 50U and below top side 24.

Fins 50 each have a cavity running through them in which heat pipes 52 can be placed. The cavities in fins 50 can either be formed in fins 50 during manufacturing of chassis 10, or the cavities can be cut into fins 50 after chassis 10 is manufactured using any suitable manufacturing process, for instance drilling. In the embodiment shown, heat pipes 52 are placed longitudinally through fins 50 so that first ends of heat pipes 52 are positioned near a second end of chassis 10 and a second end of heat pipes 52 are positioned near a first end of chassis 10. Heat pipe 52A is placed in fin 50A; heat pipe 52B is placed in fin 50B; heat pipe 52C is placed in fin 50C; heat pipe 52D is placed in fin 50D; heat pipe 52E is placed in fin 50E; heat pipe 52F is placed in fin 50F; heat pipe 52G is placed in fin 50G; heat pipe 52H is placed in fin 50H; heat pipe 52I is placed in fin 50I; heat pipe 52J is placed in fin 50J; heat pipe 52K is placed in fin 50K; heat pipe 52L is placed in fin 50L; heat pipe 52M is placed in fin 50M; heat pipe 52N is placed in fin 50N; heat pipe 52O is placed in fin 50O; heat pipe 52P is placed in fin 50P; heat pipe 52Q is placed in fin 50Q; heat pipe 52R is placed in fin 50R; heat pipe 52S is placed in fin 50S; heat pipe 52T is placed in fin 50T; heat pipe 52U is placed in fin 50U; and heat pipe 52V is placed in fin 50V. In alternate embodiments, heat pipes 52 can be placed longitudinally through fins 50 but only extend a predetermined distance through heat pipes 52 from a first location to a second location. This placement is advantageous when chassis 10 is being used for particular applications with hot electronic components positioned in particular locations in chassis 10, as a first end of heat pipe 52 can be positioned near the hot electronic component and a second end of heat pipe 52 can be positioned in a cooler location.

Heat pipes 52 are positioned in fins 50 to transfer heat through heat pipes 52 to a cooler location. Heat pipes 52 are sized and shaped to fit in the cavities in fins 50 and can be held in place in fins 50 with any suitable means. In the embodiment shown, heat pipes 52 each include a hollow housing. The housing can contain a working fluid that is capable of two-phase heat transfer and a wick material on interior surfaces of the housing to wick the working fluid from the second end of heat pipes 52 to the first end of heat pipes 52. Heat from chassis 10 will enter heat pipes 52 at the first end of heat pipes 52, causing the working fluid to vaporize. The vaporized working fluid can then be transferred through heat pipe 52. The vaporized working fluid can then release the heat from the second end of heat pipe 52 into an ambient, causing the working fluid to condense. The wick material can then transfer the condensed working fluid back to the first end of heat pipes 52. Heat pipes 52 can be constructed out of any suitable materials, including any suitable housing material, any suitable working fluid, and any suitable wick material. In alternate embodiments, fins 50 can act as the hollow housing for heat pipes 52 and heat pipes 52 can be formed in chassis 10 when chassis 10 is manufactured.

Heat pipes 52 are placed in fins 50 to increase the cooling abilities of chassis 10. As discussed with reference to FIG. 1, chassis 10 primarily dissipates heat through convection. When convective heat transfer is relied upon for cooling, chassis 10 is limited in where it can be positioned on an aircraft, as cooling airflow is required to cool chassis 10. Thus, if chassis 10 is mounted in a location on aircraft 10 with low airflow, the cooling abilities of chassis 10 will become less effective. Relying solely on cooling airflow to cool chassis 10 limits where chassis 10 can be used in aircraft 10.

Placing heat pipes 52 in fins 50 of chassis 10 is advantageous, as heat pipes 52 increase the effectiveness of the cooling abilities of chassis 10. Heat pipes 52 will transfer heat with phase-change heat transfer, thus chassis 10 no longer relies solely on convection cooling to cool chassis 10. This increase the flexibility of where chassis 10 can be positioned in an aircraft, including areas where cooling airflow is more limited. Chassis 10 can also be placed in higher temperature environments, as the heat can be more effectively spread through chassis 10 and dissipated in an ambient with heat pipes 52. Further, increasing the cooling abilities of chassis 10 means higher heat generating and more powerful electronic components can be placed on printed wiring boards in chassis 10, as chassis 10 can more effectively cool these components compared to prior cooling arrangements.

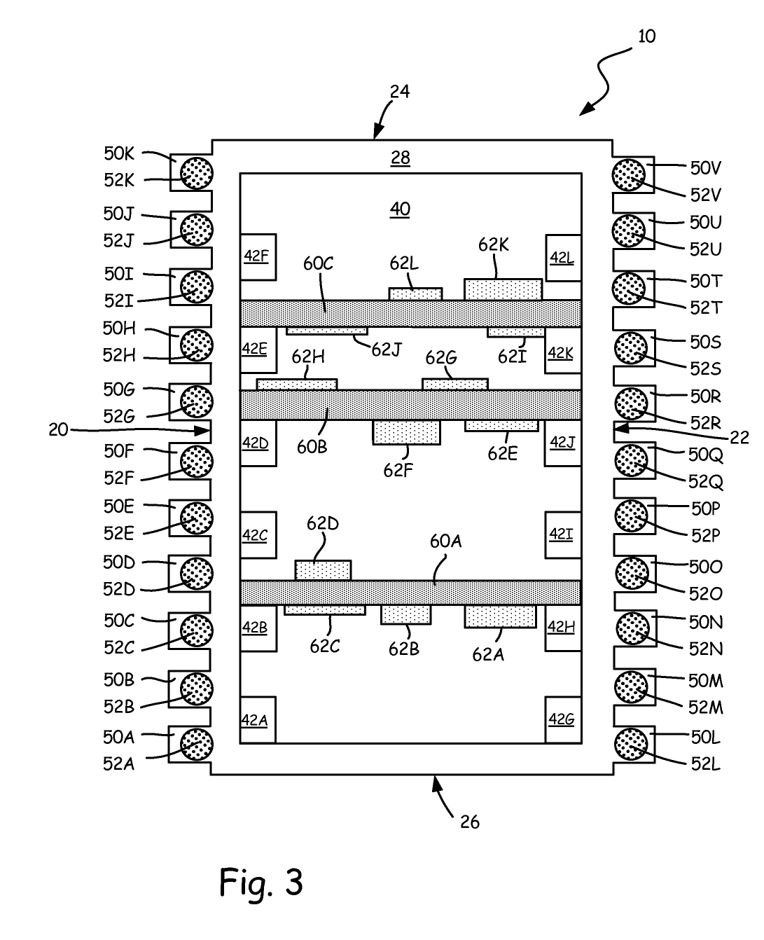

FIG. 3 is a cross-sectional view of chassis 10 with printed wiring boards 60, taken along line 2-2 of FIG. 1. Chassis 10 includes first side 20, second side 22, top side 24, bottom side 26, cavity 40, ledges 42 (including ledge 42A, ledge 42B, ledge 42C, ledge 42D, ledge 42E, ledge 42F, ledge 42G, ledge 42H, ledge 42I, ledge 42J, ledge 42K, and ledge 42L), fins 50 (including fin 50A, fin 50B, fin 50C, fin 50D, fin 50E, fin 50F, fin 50G, fin 50H, fin 50I, fin 50J, fin 50K, fin 50L, fin 50M, fin 50N, fin 50O, fin 50P, fin 50Q, fin 50R, fin 50S, fin 50T, fin 50U, and fin 50V), and heat pipes 52 (including heat pipe 52A, heat pipe 52B, heat pipe 52C, heat pipe 52D, heat pipe 52E, heat pipe 52F, heat pipe 52G, heat pipe 52H, heat pipe 52I, heat pipe 52J, heat pipe 52K, heat pipe 52L, heat pipe 52M, heat pipe 52N, heat pipe 52O, heat pipe 52P, heat pipe 52Q, heat pipe 52R, heat pipe 52S, heat pipe 52T, heat pipe 52U, and heat pipe 52V). Also included are printed wiring boards 60 (including printed wiring board 60A, printed wiring board 60B, and printed wiring board 60C) and electronic components 62 (including electronic component 62A, electronic component 62B, electronic component 62C, electronic component 62D, electronic component 62E, electronic component 62F, electronic component 62G, electronic component 62H, electronic component 62I, electronic component 62J, electronic component 62K, and electronic component 62L).

Chassis 10 has cavity 40 running from a first end of chassis 10 to a second end of chassis 10. Printed wiring boards 60 can be placed in cavity 40 of chassis 10 and supported by ledges 42. A first edge of printed wiring board 60 can be positioned on one ledge 42 on the first interior surface of cavity 40 and a second edge of printed wiring board 60 can be positioned on one ledge 42 on the second interior surface of cavity 40. Printed wiring boards 60 are positioned in cavity 40 by press fitting printed wiring boards 60 between the first interior surface and the second interior surface of cavity 40. This will suspend the printed wiring board in cavity 40 of chassis 10. Ledge 42A and ledge 42G are positioned across from one another to support a printed wiring board between them; ledge 42B and ledge 42H are positioned across from one another to support a printed wiring board between them; ledge 42C and ledge 42I are positioned across from one another to support a printed wiring board between them; ledge 42D and ledge 42J are positioned across from one another to support a printed wiring board between them; ledge 42E and ledge 42K are positioned across from one another to support a printed wiring board between them; and ledge 42F and ledge 42L are positioned across from one another to support a printed wiring board between them. In the embodiment shown in FIG. 3, printed wiring board 60A is suspended between ledge 42B and ledge 42H; printed wiring board 60B is suspended between ledge 42D and ledge 42J; and printed wiring board 60C is suspended between ledge 42E and ledge 42K. In alternate embodiments, the number of printed wiring boards 60 can vary and the arrangement of printed wiring boards 60 in cavity 40 can vary.

Electronic components 62 are positioned on printed wiring boards 60 in cavity 40. Electronic components 62 can be positioned on both a top side and a bottom side of printed wiring boards 60. Electronic component 62A, electronic component 62B, and electronic component 62C are positioned on a bottom side of printed wiring board 60A; electronic component 62D is positioned on a top side of printed wiring board 62A; electronic component 62E and electronic component 62F are positioned on a bottom side of printed wiring board 60B; electronic component 62G and electronic component 62H are positioned on a top side of printed wiring board 60B; electronic component 62I and electronic component 62J are positioned on a bottom side of printed wiring board 60C; and electronic component 62K and electronic component 62L are positioned on a top side of printed wiring board 60C.

Fins 50 are positioned on first side 20 of chassis 10 and second side 22 of chassis 10 in the embodiment shown in FIG. 3. In alternate embodiments, fins 50 can be positioned on any number of sides of chassis 10. Fins 50 extend outwardly from chassis 10 and each fin 50 has one heat pipe 52 placed in it. Heat pipes 52 run longitudinally through fins 50 and are positioned to transfer heat from a first end of heat pipe 52 to a second end of heat pipe 52 to better dissipate heat through chassis 10.

In the embodiment shown in FIG. 3, hotter electronic components 62 will be placed near edges of printed wiring board 60. With this arrangement, the heat from the hotter electronic components 62 can transfer more directly to chassis 10. The heat from electronic components 62 will transfer into ledges 42 and the first interior surface and second interior surface of cavity 40 of chassis 10. The heat will then flow through chassis 10 to fins 50. The heat that transfers to fins 50 can then be absorbed by heat pipe 52 at a first end. Absorbing heat into heat pipe 52 will cause the working fluid to vaporize. The vaporized working fluid can then flow through heat pipe 52 to a second end of heat pipe 52 where it will be released from heat pipe 52 through fin 50 to an ambient, thus cooling chassis 10.

Chassis 10 is typically cooled solely by flowing cooling air over fins 50 to cool chassis 10 with convective heat transfer. This arrangement is limited in application, as placing chassis 10 in areas with low airflow limits the cooling abilities of chassis 10. Placing heat pipes 52 in fins 50 of chassis 10 and transferring heat from hot electronic components 62 to cooler locations through heat pipes 52 is advantageous, as it provides more effective heat transfer through fins 50 of chassis 10. Heat pipes 52 can absorb heat from hot electronic components 62 on printed wiring boards 60 and transfer the heat through fin 50 to a cooler location in chassis 10. The heat that is transferred to the cooler location can then be released into an ambient through fin 50. Chassis 10 is cooled by flowing cooling air over fins 50 to cool chassis 10 with convective heat transfer. The combination of convective heat transfer provided by fins 50 and phase-change heat transfer provided by heat pipes 52 increases the overall cooling effectiveness of chassis 10.

Having more effective cooling abilities allows higher heat generating and higher power electronic components 62 to be used on printed wiring boards 60 that are placed in chassis 10. These electronic components 62 are typically smaller than previously used electronic components, which gives the added benefit of reducing the overall size and weight of chassis 10. Reducing the weight of components in aircrafts is advantageous, as aircrafts function more efficiently at lower weights. Further, space in aircrafts is limited, so being able to use smaller electronic components will save valuable space.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

1. A device with increased heat dissipation abilities for supporting printed wiring boards comprising:
a chassis for holding printed wiring boards;
a plurality of fins attached to the chassis; and
a heat pipe in each of the plurality of fins that is capable of transferring heat from the chassis to the surrounding ambient by absorbing heat from the chassis at a first end of the heat pipe and releasing the heat into the ambient at a second end of the heat pipe.

2. The device of claim 1, wherein the heat is transferred from the printed wiring boards to the chassis to heat the chassis and cool the printed wiring boards.

3. The device of claim 1, wherein the heat pipes contain a working fluid that is capable of phase-change heat transfer.

4. The device of claim 3, wherein the working fluid vaporizes at the first end of the heat pipe as the heat pipe absorbs heat from the chassis.

5. The device of claim 4, wherein the working fluid condenses at the second end of the heat pipe as the heat pipe releases the heat into the ambient.

6. The device of claim 5, wherein an interior surface of the heat pipes are covered with a wick structure layer that is capable of wicking the working fluid.

7. The device of claim 1, wherein the chassis is cooled by convective heat transfer as cooling air flows around the fins.

8. The device of claim 1, wherein heat generating electronic components are placed near edges of the printed wiring boards that are close to the chassis to effectively transfer heat from the electronic components to the chassis and then to the first ends of the heat pipes.

9. The device of claim 1, wherein the second ends of the heat pipes are positioned at cool locations in the chassis so that heat can be effectively dissipated from the chassis.

10. A device with increased heat dissipation abilities for supporting printed wiring boards comprising:
a housing that supports a plurality of printed wiring boards on ledges that run along interior surfaces of the housing;
a plurality of fins connected to a first side and a second side of the housing;
a cavity in each of the plurality of fins; and
a heat pipe in the cavity in each of the plurality of fins to transfer heat generated by the printed wiring boards in the housing to an ambient surrounding the housing.

11. The device of claim 10, wherein the cavities are drilled into the fins after the chassis is manufactured.

12. The device of claim 10, wherein the chassis is manufactured with cavities in the fins.

13. The device of claim 10, wherein the heat pipes are bonded into the cavities in the fins.

14. The device of claim 10, wherein the heat pipes contain a working fluid that is capable of phase-change heat transfer.

15. The device of claim 14, wherein an interior surface of the heat pipes are covered with a wick structure layer that is capable of wicking the working fluid.

16. A method for cooling printed wiring boards comprising:
transferring heat generated on a printed wiring board to a chassis in which the printed wiring board is held;
absorbing heat into a heat pipe that is positioned in a hollow fin on the chassis;
transferring the heat through the heat pipe; and
releasing the heat from the heat pipe into an ambient.

17. The method of claim 16, wherein a first end of the heat pipe is positioned near a heat generating electronic component that is held on the printed wiring board to effectively absorb heat from the heat generating electronic component through the chassis and into the first end of the heat pipe.

18. The method of claim 16, wherein a second end of the heat pipe is positioned at a cool location in the chassis to effectively dissipate heat out of the second end of the heat pipe and out of the chassis.

19. The method of claim 16, wherein there are a plurality of fins on a first side and a second side of the chassis.

20. The method of claim 19, wherein each of the fins contains a heat pipe running longitudinally through each of the fins.
